(19) United States
(12) Patent Application Publication
(10) Pub. No.: US 2025/0359330 A1
(43) Pub. Date: Nov. 20, 2025

(54) DISPALY PANEL AND DISPLAY DEVICE

(71) Applicant: WUHAN CHINA STAR OPTOELECTRONICS TECHNOLOGY CO., LTD., Wuhan, Hubei (CN)

(72) Inventor: Zhuang LI, Wuhan, Hubei (CN)

(73) Assignee: WUHAN CHINA STAR OPTOELECTRONICS TECHNOLOGY CO., LTD., Wuhan, Hubei (CN)

(21) Appl. No.: 18/870,634

(22) PCT Filed: Jun. 30, 2023
(86) PCT No.: PCT/CN2023/104679

§ 371 Date: Nov. 29, 2024

(30) Foreign Application Priority Data
Nov. 14, 2022 (CN) 202211419048.7

(51) Int. Cl. H10D 86/40; G02F 1/1368

(52) U.S. Cl. CPC H10D 86/421; G02F 1/1368

(57) ABSTRACT

The present application provides a display panel and a display device. The display panel comprises a substrate and an active layer; the active layer comprises a channel portion and doped portions; the doped portions are arranged on two opposite sides of the channel portion in a first direction; the channel portion is divided into a middle area and edge areas located on two opposite sides of the middle area in a second direction, and the doping concentration of the channel portion in the edge areas is greater than that in the middle area.

### TECHNICAL FIELD

The present disclosure relates to the field of display technologies, and in particular to a display panel and a display device.

### BACKGROUND

Low temperature polysilicon thin film transistors are key components of active driving and peripheral circuits in display devices such as Liquid Crystal Displays (LCD) and Organic Light Emitting Diodes (OLED).

### SUMMARY

Currently, a parasitic channel of the low temperature polysilicon thin film transistor at an inclination angle of edge regions on both sides of an active layer is turned on in advance due to a difference between a threshold voltage at the inclination angle and a threshold voltage at a middle region of the active layer, resulting in a hump effect.

In view of the foregoing, the thin film transistor in the conventional display panel has the hump effect. Therefore, there is a need to provide a display panel and a display device to improve this disadvantage.

Embodiments of the present disclosure provide a display panel and a display device, which can reduce the difference between the threshold voltage at the inclination angle of the edge regions on both sides of the thin film transistor and the threshold voltage at the middle region of the thin film transistor to prevent the parasitic channel of the thin film transistor at the inclination angle from being turned on in advance, thereby improving the hump effect.

An embodiment of the present disclosure provides a display panel, including:
a substrate;
an active layer disposed on the substrate and including a channel portion and doping portions, where the doping portions are disposed at opposite sides of the channel portion in a first direction;
where the channel portion is divided into a middle region and edge regions located at opposite sides of the middle region in a second direction, a doping concentration of the channel portion in the edge regions is greater than a doping concentration of the middle region, and the first direction intersects the second direction.

According to an embodiment of the present disclosure, a portion of the channel portion in the middle region is an extrinsic semiconductor.

According to an embodiment of the present disclosure, the channel portion is doped with first ions, the doping portions are doped with second ions, and an electric property of the first ions is opposite to an electric property of the second ions.

According to an embodiment of the present disclosure, the doping portion are doped with the first ions, and a doping concentration of the first ions in the doping portions is less than a doping concentration of the second ions in the doping portions.

According to an embodiment of the present disclosure, each of the doped portions includes a heavily doped portion and a lightly doped portion disposed between the heavily doped portion and the channel portion;
where the doping concentration of the second ions in the heavily doped portion is greater than the doping concentration of the second ions in the lightly doped portion.

According to an embodiment of the present disclosure, the lightly doped portion includes a first lightly doped portion and a second lightly doped portion disposed between the first lightly doped portion and the channel portion;
where the doping concentration of the second ions in the heavily doped portion is greater than the doping concentration of the second ions in the first lightly doped portion, and the doping concentration of the second ions in the first lightly doped portion is greater than the doping concentration of the second ions in the second lightly doped portion.

According to an embodiment of the present disclosure, a doping concentration of first ions of the channel portion in the edges region is less than the doping concentration of the second ions in the second lightly doped portion.

According to an embodiment of the present disclosure, a thickness of each of the edges region is gradually reduced from an end of the edge region close to the middle region to another end of the edge region away from the middle region.

According to an embodiment of the present disclosure, the active layer includes a first surface, a second surface, and a sidewall respectively connected to the first surface and the second surface and obliquely disposed, and the second surface is disposed on a side of the first surface away from the substrate;
where the sidewall is disposed in the edge regions, the first surface is disposed in the middle region and the edge regions, and the second surface is disposed in at least the middle region.

According to an embodiment of the present disclosure, an included angle between the sidewall and the second surface is between 50 degrees and 80 degrees.

Another embodiment of the present disclosure further provides a display device, including a display panel including:
a substrate;
an active layer disposed on the substrate and including a channel portion and doping portions, where the doping portions are disposed at opposite sides of the channel portion in a first direction;
where the channel portion is divided into a middle region and edge regions located at opposite sides of the middle region in a second direction, a doping concentration of the channel portion in the edge regions is greater than a doping concentration of the middle region, and the first direction intersects the second direction.

According to an embodiment of the present disclosure, a portion of the channel portion in the middle region is an extrinsic semiconductor.

According to an embodiment of the present disclosure, the channel portion is doped with first ions, the doping portions are doped with second ions, and an electric property of the first ions is opposite to an electric property of the second ions.

According to an embodiment of the present disclosure, the doping portions are doped with the first ions, and a doping concentration of the first ions in the doping portions is less than a doping concentration of the second ions in the doping portions.

According to an embodiment of the present disclosure, each of the doped portions includes a heavily doped portion and a lightly doped portion disposed between the heavily doped portion and the channel portion;
where the doping concentration of the second ions in the heavily doped portion is greater than the doping concentration of the second ions in the lightly doped portion.

According to an embodiment of the present disclosure, the lightly doped portion includes a first lightly doped portion and a second lightly doped portion disposed between the first lightly doped portion and the channel portion;
where the doping concentration of the second ions in the heavily doped portion is greater than the doping concentration of the second ions in the first lightly doped portion, and the doping concentration of the second ions in the first lightly doped portion is greater than the doping concentration of the second ions in the second lightly doped portion.

According to an embodiment of the present disclosure, a doping concentration of the first ions of the channel portion in the edges region is less than the doping concentration of the second ions in the second lightly doped portion.

According to an embodiment of the present disclosure, a thickness of each of the edges region is gradually reduced from an end of the edge region close to the middle region to another end of the edge region away from the middle region.

According to an embodiment of the present disclosure, the active layer includes a first surface, a second surface, and a sidewall respectively connected to the first surface and the second surface and obliquely disposed, and the second surface is disposed on a side of the first surface away from the substrate;
where the sidewall is disposed in the edge regions, the first surface is disposed in the middle region and the edge regions, and the second surface is disposed in at least the middle region.

According to an embodiment of the present disclosure, an included angle between the sidewall and the second surface is between 50 degrees and 80 degrees.

### Beneficial Effects

Beneficial effects of the embodiments of the present disclosure are that the embodiments of the present disclosure provide a display panel and a display device, where the display panel includes a substrate and an active layer, the active layer is disposed on the substrate and includes a channel portion and a doping portion, the doping portion is disposed at opposite sides of the channel portion in a first direction, the channel portion is divided into a middle region and edge regions located at opposite sides of the middle region in a second direction. By making a doping concentration of the channel portion in the edge regions be greater than a doping concentration of the channel portion in the middle region, it is possible to reduce the difference between the threshold voltage of the thin film transistor in the edge regions and the threshold voltage of the thin film transistor in the middle region to prevent the parasitic channel of the thin film transistor in the edge regions from being turned on in advance, thereby improving the hump effect.

### BRIEF DESCRIPTION OF THE DRAWINGS

In order to more clearly illustrate the technical solutions in embodiments of the present disclosure, the accompanying drawings depicted in the description of the embodiments will be briefly described below. It will be apparent that the accompanying drawings in the following description are merely some embodiments of the present disclosure, and other drawings may be obtained from these drawings without creative effort by those skilled in the art.

FIG. 1 is a schematic plan view of a first type of thin film transistor according to an embodiment of the present disclosure.

FIG. 2 is a schematic cross-sectional view of a first type of thin film transistor in a direction A-A according to an embodiment of the present disclosure.

FIG. 3 is a schematic cross-sectional view of a first type of thin film transistor in a direction B-B according to an embodiment of the present disclosure.

FIG. 4 is a schematic cross-sectional view of another type of thin film transistor in a direction B-B according to an embodiment of the present disclosure.

FIG. 5 is a schematic plan view of a second type of thin film transistor according to an embodiment of the present disclosure.

FIG. 6 is a schematic cross-sectional view of a second type of thin film transistor in a direction A-A according to an embodiment of the present disclosure.

FIG. 7 is a schematic plan view of a third type of thin film transistor according to an embodiment of the present disclosure.

FIG. 8 is a schematic plan view of an active layer of a third type of thin film transistor according to an embodiment of the present disclosure.

FIG. 9 is a schematic cross-sectional view of a third type of thin film transistor in a direction A-A according to an embodiment of the present disclosure.

FIGS. 10a-10p are flow diagrams of a method for manufacturing a display panel according to an embodiment of the present disclosure.

### DETAILED DESCRIPTION

The description of the following embodiments refers to the attached drawings to illustrate specific embodiments in which the present application can be implemented. The directional terms mentioned in the present disclosure, such as [up], [down], [front], [back], [left], [right], [inner], [outer], [side], etc., are only the direction of the attached drawings. Therefore, the directional terms used are used to describe and understand the present disclosure, rather than to limit the present disclosure. In the drawings, units with similar structures are indicated by the same reference numerals.

The present disclosure is illustrated below with reference to the accompanying drawings and specific embodiments.

Embodiments of the present disclosure provide a display panel, which can reduce the difference between the threshold voltage at the inclination angle of the edge regions on both sides of the active layer and the threshold voltage at the middle region of the active layer to prevent the parasitic channel of the thin film transistor at the inclination angle from being turned on in advance, thereby improving the hump effect.

An embodiment of the present disclosure provides a display panel, including: a substrate 10 and a driving circuit layer disposed on the substrate 10, where a plurality of thin film transistors are disposed in the driving circuit layer.

It should be noted that being disposed on the substrate 10 may refer to being disposed in direct contact with the substrate 10 or in indirect contact with the substrate 10.

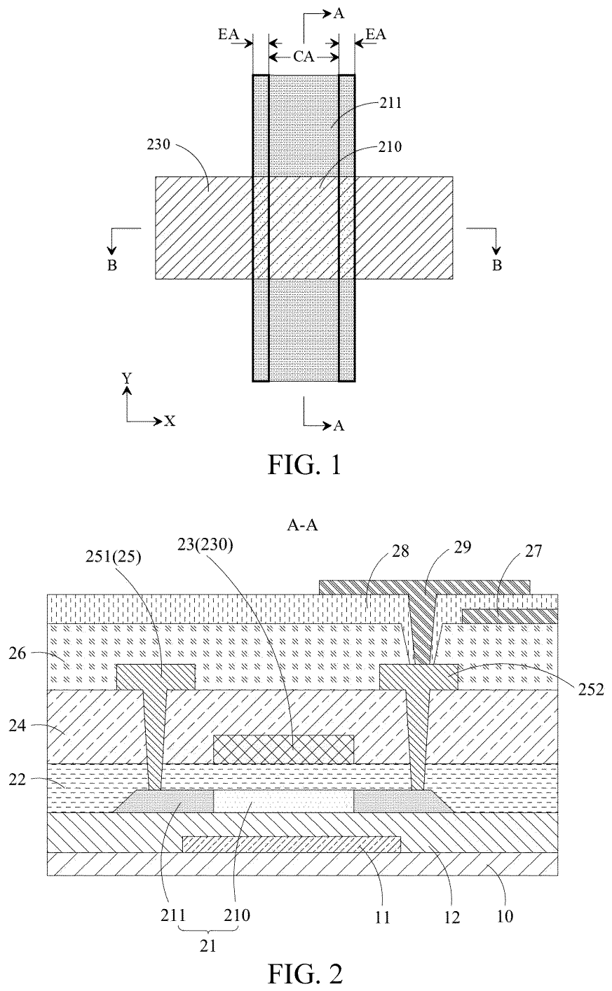

In the embodiment of the present disclosure, as shown in FIG. 2, the display panel may further include a light shielding layer 11 disposed on the substrate 10, and a buffer layer 12 disposed on the substrate 10 and covering the light shielding layer 11, where the driving circuit layer is disposed on the buffer layer 12.

The driving circuit layer may include, but is not limited to, an active layer 21, a gate insulation layer 22, a first metal layer 23, an interlayer dielectric layer 24, a second metal layer 25, a flat layer 26, a first electrode layer 27, a passivation layer 28, and a second electrode layer 29, which are sequentially stacked on the substrate 10.

As shown in FIG. 2, the active layer 21 is dispose on a side of the buffer layer 12 away from the substrate 10, and may include a channel portion 210 and doping portions 211, and the doping portions 211 are disposed on opposite sides of the channel portion 210 in a first direction Y.

The first metal layer 23 is disposed on a side of the gate insulation layer 22 away from the substrate 10, and the first metal layer 23 may include a plurality of patterned gates 230, the gate 230 is disposed right on the channel portion 210, and an orthographic projection of the gate 230 on the substrate 10 may overlap an orthographic projection of the channel portion 210 on the substrate 10.

The second metal layer 25 is disposed on a side of the interlayer dielectric layer 24 away from the substrate 10, and the second metal layer 25 may include a source 251 and a drain 252, where the source 251 contacts one of the doping portions 211 of the active layer 21 through one via hole on the interlayer dielectric layer 24 and the gate insulation layer 22, and a drain electrode 252 contacts another of the doping portions 211 of the active layer 21 through another via hole on the interlayer dielectric layer 24 and the gate insulation layer 22.

The first electrode layer 27 is disposed on a side of the flat layer 26 away from the substrate 10, and the second electrode layer 29 is disposed on a side of the passivation layer 28 away from the substrate 10 and may include a plurality of patterned pixel electrodes.

The display panel provided in the embodiment of the present disclosure is a liquid crystal display panel, the first electrode layer 27 may be used as a common electrode, and an electric field is formed between the first electrode layer 27 and a pixel electrode in the second electrode layer 29 for driving deflection of liquid crystal molecules.

It should be noted that the embodiment of the present disclosure is illustrated by taking only a liquid crystal display panel as an example, and a technical solution of the present disclosure is also applicable to other types of display panels such as an organic light emitting diode display panel, a micro light emitting diode display panel (Micro LED), and a miniature light emitting diode display panel (Mini LED).

As shown in FIG. 1, the channel portion 210 may be divided into a middle region CA and edge regions EA in a second direction X, the edge regions EA are located at opposite sides of the middle region CA in the second direction X, and the first direction Y intersects the second direction X.

In the embodiment of the present disclosure, the first direction Y may refer to a direction of the active layer 21 from one side of the channel portion 210 to another side of the channel portion 210, that is, a channel length direction of the thin film transistor. The second direction X may be perpendicular to the first direction Y and may be a channel width direction of the thin film transistor, and the third direction Z may be perpendicular to both the first direction Y and the second direction X at the same time and may be a thickness direction of the display panel.

In the embodiment of the present disclosure, a doping type of the channel portion 210 is different from that of the doping portions 211, that is, the channel portion 210 is doped with first ions, the doping portions 211 are doped with second ions, and an electric property of the first ions is different from an electric property of the second ions. For example, the channel portion 210 is P-type doped, the first ions are P-type ions, the doped portion is N-type doped, and the second ions are N-type ions. Alternatively, the channel portion 210 is N-type doped, the first ions are N-type ions, the doped portion is P-type doped, and the second ions are P-type ions.

A doping concentration of the channel portion 210 in the edge regions EA is greater than a doping concentration of the channel portion 210 in the middle region CA. That is, the doping concentration of the first ions of the channel portion 210 in the edge regions EA is greater than the doping concentration of the first ions of the channel portion 210 in the middle region CA.

In the embodiment of the present disclosure, a type of thin film transistor is an N-type thin film transistor, and the material of the active layer 21 is silicon, where the morphology of silicon is polysilicon. The channel portion 210 is P-type doped, the first ions may be boron ions, the doped portions 211 are N-type doped, and the second ions may be phosphorus ions.

By taking the N-type thin film transistor of the embodiment of the present disclosure as an example, a thickness of each of the edge regions EA is gradually decreased from an end of the edge region EA close to the middle region CA to another end of the edge region EA away from the middle region CA, and the thickness of the gate insulation layer 22 above the edge regions EA of the active layer 21 is thinner than the thickness of the gate insulation layer 22 above the middle region CA of the active layer 21, so that the threshold voltage of the thin film transistor in the edge regions EA drifts negatively, and the threshold voltage of the thin film transistor in the edge regions EA is biased negatively compared to the threshold voltage of the thin film transistor in the middle region CA. As such, the parasitic channel of the thin film transistor in the edge regions EA is turned on in advance, resulting in a hump effect. By increasing and making the doping concentration of the channel portion 210 in the edge regions EA be greater than the doping concentration of the channel portion 210 in the middle region CA, the embodiment of the present disclosure can reduce the difference between the threshold voltage of the thin film transistor in the edge regions EA and the threshold voltage of the thin film transistor in the middle region CA, so that the parasitic channel of the edge regions EA can be prevented from being turned on in advance, thereby improving the hump effect.

In an embodiment, the thin film transistor may also be a P-type thin film transistor, the channel portion 210 is N-type doped, the first ions may be, but is not limited to, phosphor ions, the doped portions 211 are P-type doped, and the second ions may be, but is not limited to, boron ions. By increasing and making the doping concentration of the channel portion 210 in the edge regions EA be greater than the doping concentration of the channel portion 210 in the middle region CA, the difference between the threshold voltage of the thin film transistor in the edge regions EA and the threshold voltage of the thin film transistor in the middle region CA can be reduced, so that the parasitic channel of the edge regions EA can be also prevented from being turned on in advance, thereby improving the hump effect.

Further, the active layer 21 includes a first surface a1, a second surface a2, and a sidewall a3 respectively connected to the first surface a1 and the second surface a2 and obliquely disposed, the second surface a2 is disposed on a side of the first surface a1 away from the substrate 10, the sidewall a3 is disposed in the edge regions EA, the first surface a1 is disposed in the middle region CA and the edge regions EA, and the second surface a2 is disposed in at least the middle region CA.

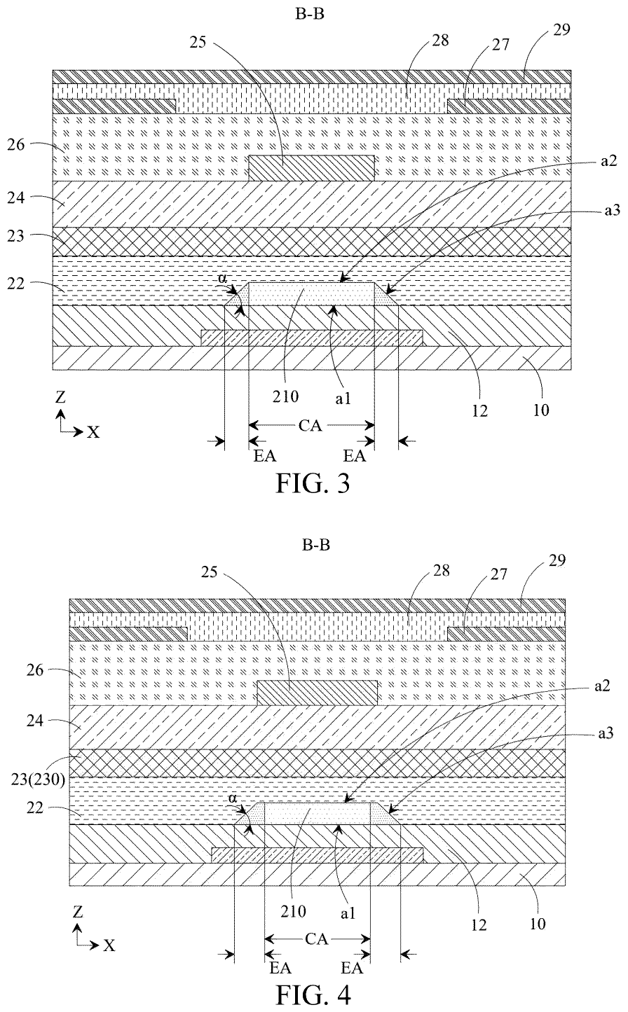

In an embodiment, as shown in FIG. 3, the second surface a2 is disposed only in the middle region CA, and a cross-sectional shape of the active layer 21 in the edge regions EA may be a right triangle.

Further, an included angle α between the sidewall a3 and the first surface a1 is between 50 degrees and 80 degrees. As such, it is possible to prevent the threshold voltage of the edge regions EA from being biased negatively and more serious due to an excessive slope of the sidewall a3, while it is also possible to prevent the gate insulation layer 22 from being broken due to the excessive slope of the sidewall a3.

Specifically, the included angle between the sidewall a3 and the first surface a1 may be, but is not limited to, any one of 50 degrees, 60 degrees, 70 degrees, 80 degrees, or the like.

In an embodiment, as shown in FIG. 4, the second surface a2 is disposed in the middle region CA and the edge regions EA, and the cross-sectional shape of the active layer 21 in the edge regions EA may be a right triangle. By increasing the range of the edge regions EA, accuracy requirements of related devices required for the doping process may be reduced.

In an embodiment, a portion of the channel portion 210 in the middle region CA is an extrinsic semiconductor, i.e., the middle region CA and the edge regions EA of the channel portion 210 are both doped with first ions. By doping the middle region CA of the channel portion 210, the threshold voltage of the thin film transistor can be adjusted.

In an embodiment, the doping portion 211 is doped with the first ions, the doping concentration of the first ions in the doping portions 211 is less than the doping concentration of the second ions in the doping portions 211, the doping concentration of the first ions of the doping portion 211 in the edge regions EA may be greater than or equal to the doping concentration of the first ions of the doping portion 211 in the middle region CA, and the doping concentration of the first ions in the doping portion 211 is approximately equal to the doping concentration of the first ions in the channel portion 210.

In an embodiment, the channel portion 210 may also be an intrinsic semiconductor in the middle region CA, i.e., the edge regions EA of the channel portion 210 is doped with the first ions while the middle region CA is not doped.

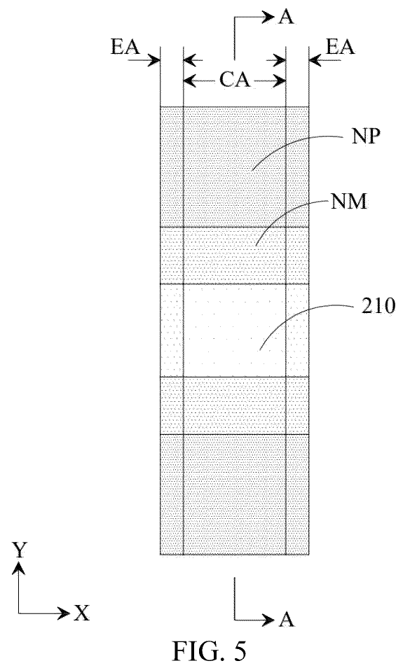

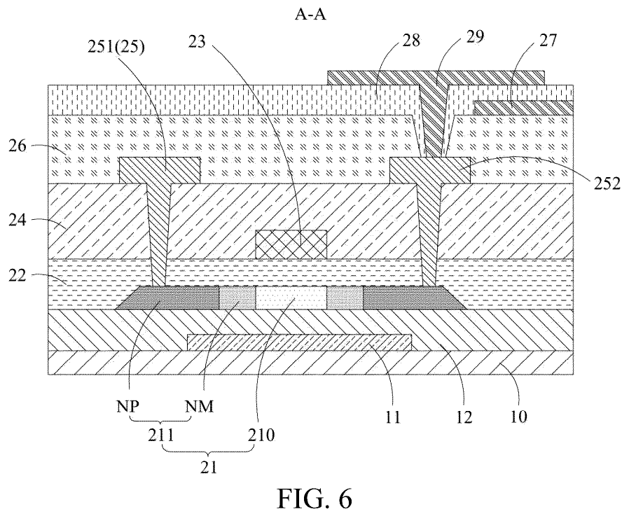

In an embodiment, as shown in FIGS. 5 and 6, the doping portion 211 may include a heavily doped portion NM and a lightly doped portion NM disposed between the heavily doped portion NP and the channel portion 210, the doping concentration of the second ions in the heavily doped portion NP is greater than the doping concentration of the second ions in the lightly doped portion NM, and the doping concentration of the second ions in the lightly doped portion NM is much greater than the doping concentration of the first ions of the channel portion 210 in the edge regions EA. By dividing the doping portion 211 into the heavily doped portion NP and the lightly doped portion NM, a drain electric field can be reduced and an off-state current can be reduced.

In the embodiment of the present disclosure, the doping concentration of the second ions of the heavily doped portion NP in the edge regions EA is equal to the doping concentration of the second ions of the heavily doped portion NP in the middle region CA, and the doping concentration of the second ions of the lightly doped portion NM in the edge regions EA is equal to the doping concentration of the second ions of the lightly doped portion NM in the middle region CA.

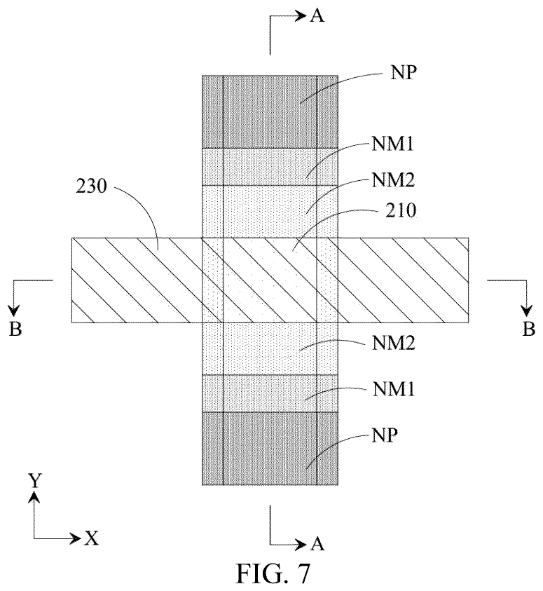

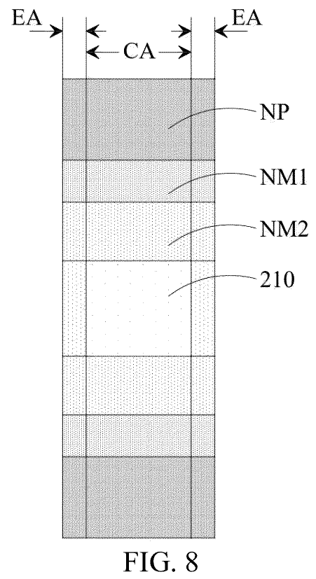

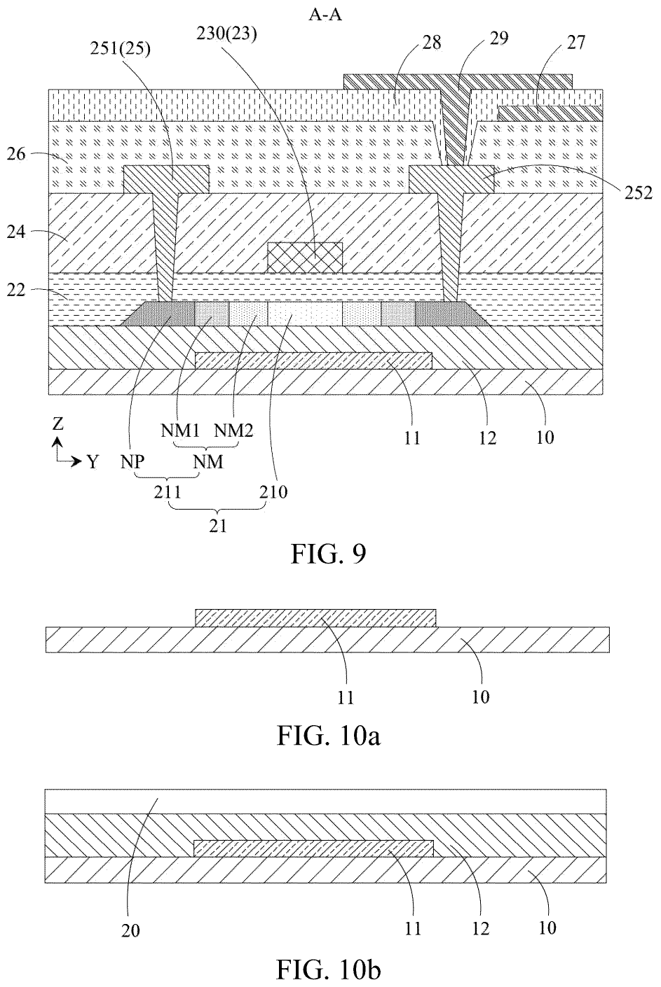

In an embodiment, as shown in FIG. 7, FIG. 8, and FIG. 9, the lightly doped portion NM includes a first lightly doped portion NM1 and a second lightly doped portion NM2, where the second lightly doped portion NM2 is disposed between the first lightly doped portion NM1 and the channel portion 210, the doping concentration of the second ions in the heavily doped portion NP is greater than the doping concentration of the second ions in the first lightly doped portion NM1, and the doping concentration of the second ions in the first lightly doped portion NM1 is greater than the doping concentration of the second ions in the second lightly doped portion NM2.

It should be noted in the embodiment shown in FIGS. 5 to 6 that, although the lightly doped portion NM can reduce an electric field of a drain 252 and reduce an off-state current, since the doping concentrations of the heavily doped portion NP to the lightly doped portion NM vary greatly and a junction electric field strength is still larger. The embodiment shown in FIGS. 7 to 9 can reduce the leakage current by providing lightly doped portions having two middle concentrations between the heavily doped portion NP and the channel portion 210, i.e., the first lightly doped portion NM1 and the second lightly doped portion NM2, to form a slow junction to reduce a junction electric field strength thereby.

The doping concentration of the second ions of the heavily doped portion NP in the edge regions EA is equal to the doping concentration of the second ions of the heavily doped portion NP in the middle region CA, the doping concentration of the second ions of the first lightly doped portion NM1 in the edge regions EA is equal to the doping concentration of the second ions of the first lightly doped portion NM1 in the middle region CA, the doping concentration of the second ions of the second lightly doped portion NM2 in the edge regions EA is equal to the doping concentration of the second ions of the second lightly doped portion NM2 in the middle region CA, and the doping concentration of the first ions of the channel portion 210 in the edge regions EA is much less than the doping concentration of the second ions of the second lightly doped portion NM2.

According to the display panel provided in the above embodiments of the present disclosure, an embodiment of the present disclosure further provides a method for manufacturing a display panel, where the method may be used for manufacturing the display panel according to the above embodiments and includes:
step S10 of forming an active layer 21 on a substrate 10, where the active layer 21 is divided into a middle region CA and edge regions EA located at opposite sides of the middle region CA in a second direction X;
step S11 of doping the edge regions EA of the active layer 21; and
step S12 of doping the active layer 21 again to form a channel portion 210 and doping portions 211.

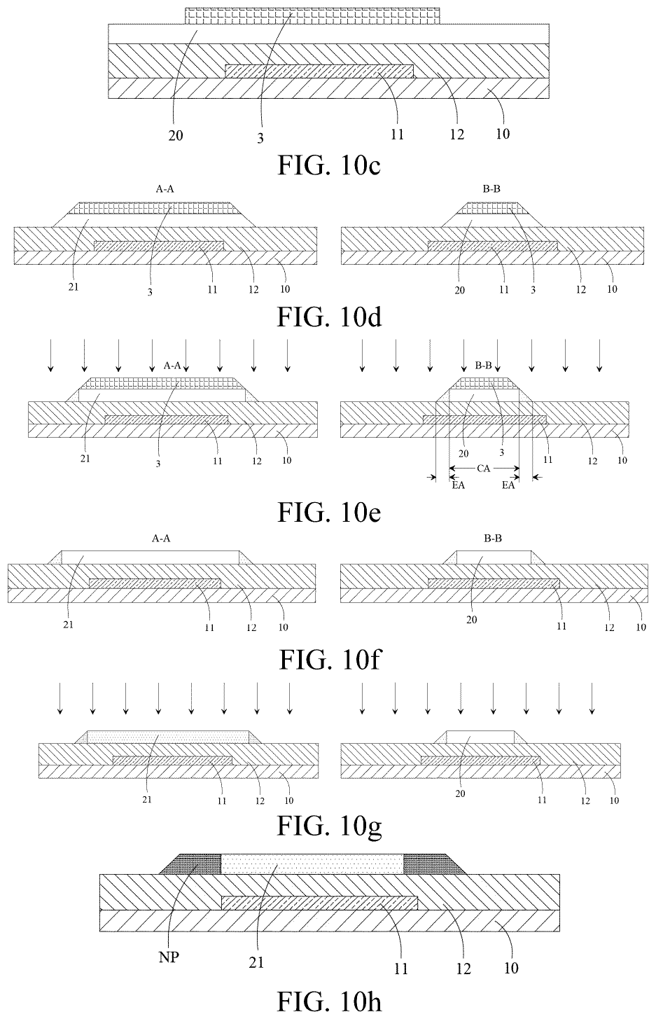

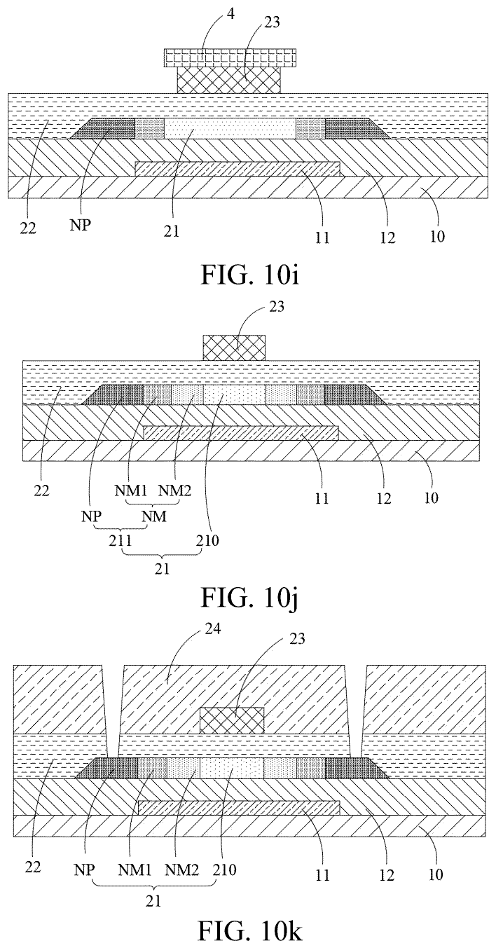

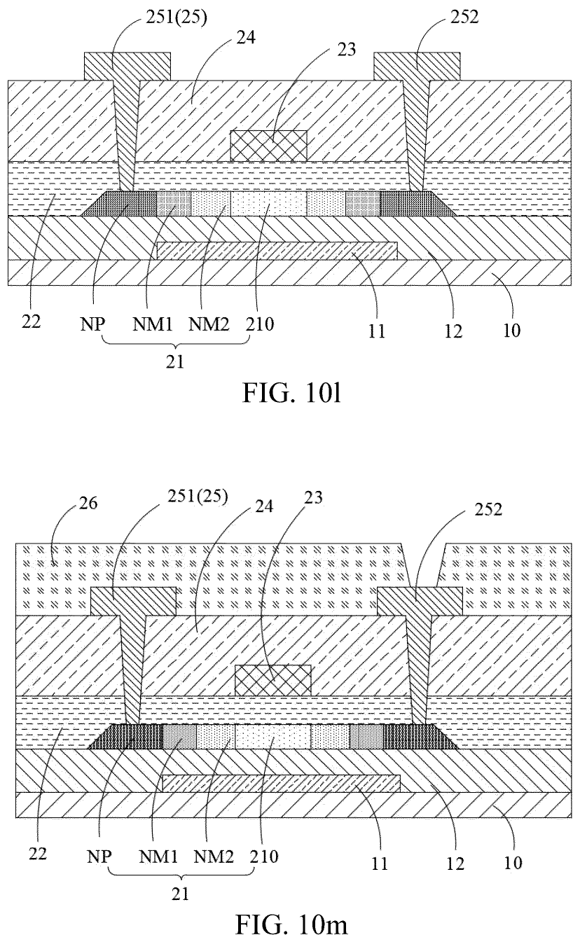

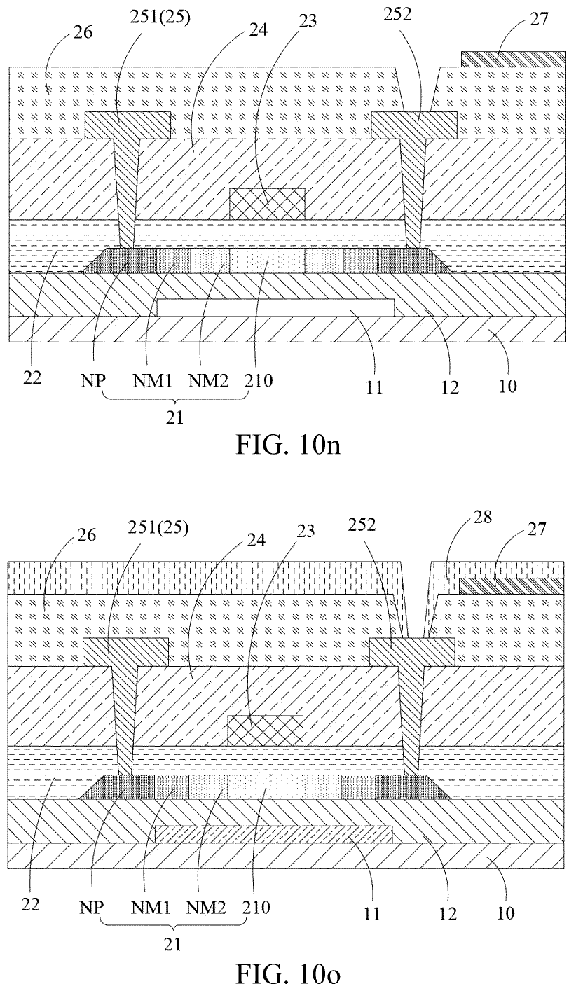

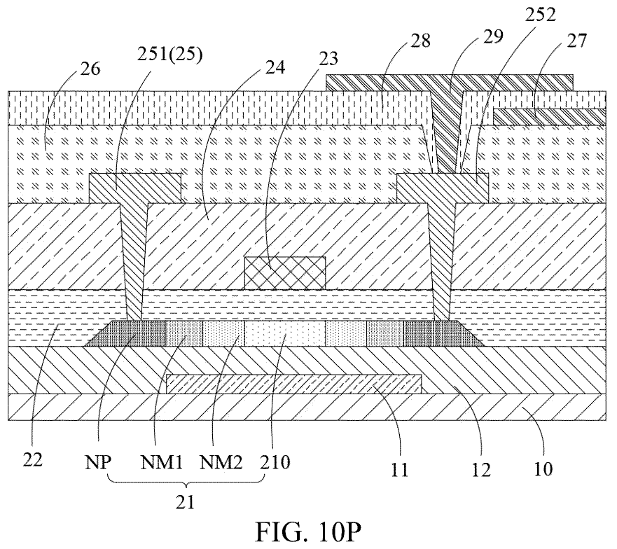

As shown in FIGS. 10a to 10d, the step S10 includes:
step S101 of forming a light shielding layer 11 on the substrate 10 as shown in FIG. 10a;
step S102 of forming a buffer layer 12 on the substrate 10, and depositing a semiconductor layer 20 on the buffer layer 12 as shown in FIG. 10b; and
step S103 of depositing a layer of photoresist on the semiconductor layer 20, and patterning the photoresist to form a first photoresist pattern 3 as shown in FIG. 10c; and
step S104 of patterning the semiconductor layer 20 to form the active layer 21 as shown in FIG. 10d.

It should be noted that FIGS. 10a to 10c and FIGS. 10h to 10p illustrate cross-sectional views of the display panel in the direction A-A, and FIGS. 10d to 10g illustrate cross-sectional views of the display panel in two directions A-A and B-B.

As shown in the cross-sectional view in the direction B-B in FIG. 10e, the active layer 21 may be divided into a middle region CA and edge regions EA located at opposite sides of the middle region CA in the second direction X, each of the edge regions EA has a sidewall obliquely disposed, and the first photoresist pattern 3 shields the middle region CA and exposes the edge regions EA.

In the embodiment of the present disclosure, the thin film transistor of the display panel is an N-type thin film transistor. In the step S11, the edge regions EA of the active layer 21 are P-doped, and first ions may be doped in the edge regions EA of the active layer 21. The first ions may be boron ions, and the doping amount for doping the edge regions EA may be, but is not limited to, 2×1012/cm2.

As shown in FIGS. 10F to 10j, the step S12 includes:
step S121 of removing the first photoresist pattern 3 as shown in FIG. 10f;
step S122 of doping an entire layer of the active layer 21 as shown in FIG. 10g;
step S123 of doping opposite ends of the active layer 21 to form a heavily doped portion NP, and covering other portion of the active layer 21 with a photoresist pattern (not shown) as shown in FIG. 10h;
step S124 of forming a gate insulation layer 22, a first metal layer 23, and a second photoresist pattern 4 sequentially on the active layer 21, the first metal layer 23 and the second photoresist pattern 4 partially cover the active layer 21, and the portion of the active layer 21 not covered by the second photoresist pattern 4 and the first metal layer 23 is doped to form a first lightly doped portion NM1 and a channel portion 210, and the first lightly doped portion NM1, the second lightly doped portion NM2, and the heavily doped portion NP together constitute the doped portion 211 as shown in FIG. 10i; and
step S125 of etching the first metal layer 23 to remove the first photoresist pattern 3, and doping the portion of the active layer 21 not covered by the first metal layer 23 to form a second lightly doped portion NM2 as shown in FIG. 10j.

Specifically, in step S122, an entire layer of the active layer 21 is doped, i.e., the middle region CA and the edge regions EA are both doped, and the doping type is P-type doped, i.e., the middle region CA and the edge regions EA of the active layer 21 are both doped with first ions, which may be boron ions. In the step S122, the doping amount for doping the active layer 21 may be, but is not limited to, 2×1012/cm2.

In the step S123, N-type doping is performed on opposite ends of the active layer 21, and the opposite ends of the active layer 21 are doped with second ions, which may be, but is not limited to, phosphorus ions, and a doping amount for doping the heavily doped portion NP may be, but is not limited to, 4×1014/cm2.

In the step S124, the portion of the active layer 21 not covered by the second photoresist pattern 4 and the first metal layer 23 is N-doped, the portion of the active layer 21 not covered by the second photoresist pattern 4 and the first metal layer 23 is doped with second ions, and a doping amount for doping the portion to form the first lightly doped portion NM1 may be, but is not limited to, 5×1013/cm2.

In the step S125, the portion of the active layer 21 not covered by the first metal layer 23 is N doped, the portion of the active layer 21 not covered by the first metal layer 23 is doped with second ions, and a doping amount for doping the portion to form the second lightly doped portion NM2 may be, but is not limited to, 1×1013/cm2.

In the process of the steps S11 to S12, the edge regions EA of the channel portion 210 is doped twice by the steps S11 and S122, the total doping amount of the edge regions EA of the channel portion 210 is 4×1012/cm2, the middle region CA of the channel portion 210 is doped only once in the step S122, and the total doping amount of the middle region CA of the channel portion 210 is 2×1012/cm2, so that the doping concentration of the first ions in the edge regions EA of the channel portion 210 is greater than the doping concentration of the first ions in the middle region CA.

Compared with the conventional N-type thin film transistor in the related art, the doping amount of the heavily doped portion is 4×1014/cm2, the doping amount of the lightly doped portion is 1×1013/cm2, and the doping amount of the channel portion is 2×1012/cm2. The doping amount of the edge regions EA of the active layer 21 can be individually adjusted by steps S10 to S11 in the embodiments of the present disclosure, so that the doping concentration of the channel portion 210 of the active layer 21 in the edge regions EA is greater than the doping concentration of the middle region CA. As such, the difference between the threshold voltage of the thin film transistor in the edge region EA and the threshold voltage of the thin film transistor in the middle region CA can be reduce, thereby improving the hump effect.

In addition, the embodiment of the present disclosure can further reduce the leakage current by providing lightly doped portions (i.e., the first lightly doped portion NM1 and the second lightly doped portion NM2) having two middle concentrations between the heavily doped portion NP and the channel portion 210 with a re-etch technology to form a slow junction to reduce a junction electric field strength thereby.

As shown in FIGS. 10k to 10p, the method for manufacturing a display panel according to an embodiment of the present disclosure further includes:
step S13 of forming an interlayer dielectric layer 24 on the gate insulation layer 22 and the first metal layer 23, and etching the interlayer dielectric layer 24 and the gate insulation layer 22 to form a plurality of via holes for exposing the heavily doped portion NP, as shown in FIG. 10k;
step S14 of forming a second metal layer 25 on the interlayer dielectric layer 24, and etching the second metal layer 25 to form a source 251 and a drain 252, as shown in FIG. 10l;
step S15 of forming a flat layer 26 on the second metal layer 25 and the interlayer dielectric layer 24, and forming a plurality of via holes on the flat layer 26 for exposing the drain 252, as shown in FIG. 10m;
step S16 of forming a first electrode layer 27 on the flat layer 26, as shown in FIG. 10n;
step S17 of forming a passivation layer 28 on the first electrode layer 27 and the flat layer 26, and forming a plurality of via holes on the passivation layer 28 for exposing the drain 252, as shown in FIG. 10o; and
step S18 of forming a second electrode layer 29 on the passivation layer 28, where the second electrode layer 29 is in contact with the drain 252 through the via holes on the passivation layer 28, as shown in FIG. 10p.

It should be noted that the method for manufacturing the display panel provided in the embodiment of the present disclosure is illustrated by taking only the display panel shown in FIGS. 7 to 9 as an example, and only partial steps of the method for manufacturing the display panel are illustrated in the embodiments of the present disclosure. Structures of other display panels not shown, and related manufacturing steps may refer to structures of existing display panels and related manufacturing steps. The method for manufacturing the display panel provided in the above embodiments is also applicable to a display panel provided in other embodiments, which is not repeatedly described herein.

Beneficial effects of the embodiments of the present disclosure are that the embodiments of the present disclosure provide a display panel, where the display panel includes a substrate and an active layer, the active layer is disposed on the substrate and includes a channel portion and a doping portion, the doping portion is disposed at opposite sides of the channel portion in a first direction, the channel portion is divided into a middle region and an edge region located at opposite sides of the middle region in a second direction. By making a doping concentration of the channel portion in the edge region be greater than a doping concentration of the channel portion in the middle region, it is possible to reduce the difference between the threshold voltage of the thin film transistor in the edge region and the threshold voltage of the thin film transistor in the middle region to prevent the parasitic channel of the thin film transistor in the edge region from being turned on in advance, thereby improving the hump effect.

According to the display panel provided in the above embodiment of the present disclosure, another embodiment of the present disclosure further provides a display device, including: a main board, a frame, and a display panel, where the main board is disposed in the frame, the display panel is fixedly disposed on the frame, the main board is electrically connected to the display panel, the display panel of the display device may be the display panel provided in any one of the above embodiments, and the structure of the display panel is not repeatedly described herein.

In summary, although preferred embodiments have been described above in the present disclosure, the above-mentioned preferred embodiments are not intended to limit the present disclosure. Those of ordinary skilled in the art can make various modifications and changes without departing from the spirit and scope of the present disclosure. Therefore, the protection scope of the present disclosure is subject to the scope defined by the claims.

What is claimed is:

1. A display panel, comprising:
a substrate;
an active layer disposed on the substrate and comprising a channel portion and doping portions, wherein the doping portions are disposed at opposite sides of the channel portion in a first direction;
wherein the channel portion is divided into a middle region and edge regions located at opposite sides of the middle region in a second direction, a doping concentration of the channel portion in the edge regions is greater than a doping concentration of the channel portion in the middle region, and the first direction intersects the second direction.

2. The display panel of claim 1, wherein a portion of the channel portion in the middle region is an extrinsic semiconductor.

3. The display panel of claim 1, wherein the channel portion is doped with first ions, the doping portions are doped with second ions, and an electric property of the first ions is opposite to an electric property of the second ions.

4. The display panel of claim 3, wherein the doping portions are doped with the first ions, and a doping concentration of the first ions in the doping portions is less than a doping concentration of the second ions in the doping portions.

5. The display panel of claim 3, wherein each of the doped portions comprises a heavily doped portion and a lightly doped portion disposed between the heavily doped portion and the channel portion;
wherein a doping concentration of the second ions in the heavily doped portion is greater than a doping concentration of the second ions in the lightly doped portion.

6. The display panel of claim 5, wherein the lightly doped portion comprises a first lightly doped portion and a second lightly doped portion disposed between the first lightly doped portion and the channel portion;
wherein the doping concentration of the second ions in the heavily doped portion is greater than a doping concentration of the second ions in the first lightly doped portion, and the doping concentration of the second ions in the first lightly doped portion is greater than a doping concentration of the second ions in the second lightly doped portion.

7. The display panel of claim 6, wherein a doping concentration of the first ions of the channel portion in the edge regions is less than the doping concentration of the second ions in the second lightly doped portion.

8. The display panel of claim 1, wherein a thickness of each of the edge regions is gradually reduced from an end of the edge region close to the middle region to another end of the edge region away from the middle region.

9. The display panel of claim 1, wherein the active layer comprises a first surface, a second surface, and a sidewall respectively connected to the first surface and the second surface and obliquely disposed, and the second surface is disposed on a side of the first surface away from the substrate;
wherein the sidewall is disposed in the edge regions, the first surface is disposed in the middle region and the edge regions, and the second surface is disposed in at least the middle region.

10. The display panel of claim 9, wherein an included angle between the sidewall and the second surface is between 50 degrees and 80 degrees.

11. A display device, comprising a display panel, wherein the display panel comprises:
a substrate;
an active layer disposed on the substrate and comprising a channel portion and doping portions, wherein the doping portions are disposed at opposite sides of the channel portion in a first direction;
wherein the channel portion is divided into a middle region and edge regions located at opposite sides of the middle region in a second direction, a doping concentration of the channel portion in the edge regions is greater than a doping concentration of the channel portion in the middle region, and the first direction intersects the second direction.

12. The display device of claim 11, wherein a portion of the channel portion in the middle region is an extrinsic semiconductor.

13. The display device of claim 11, wherein the channel portion is doped with first ions, the doping portions are doped with second ions, and an electric property of the first ions is opposite to an electric property of the second ions.

14. The display device of claim 13, wherein the doping portions are doped with the first ions, and a doping concentration of the first ions in the doping portions is less than a doping concentration of the second ions in the doping portions.

15. The display device of claim 13, wherein each of the doped portions comprises a heavily doped portion and a lightly doped portion disposed between the heavily doped portion and the channel portion;
wherein a doping concentration of the second ions in the heavily doped portion is greater than a doping concentration of the second ions in the lightly doped portion.

16. The display device of claim 15, wherein the lightly doped portion comprises a first lightly doped portion and a second lightly doped portion disposed between the first lightly doped portion and the channel portion;
wherein the doping concentration of the second ions in the heavily doped portion is greater than a doping concentration of the second ions in the first lightly doped portion, and the doping concentration of the second ions in the first lightly doped portion is greater than a doping concentration of the second ions in the second lightly doped portion.

17. The display device of claim 16, wherein a doping concentration of the first ions of the channel portion in the edge regions is less than the doping concentration of the second ions in the second lightly doped portion.

18. The display device of claim 11, wherein a thickness of each of the edge regions is gradually reduced from an end of the edge region close to the middle region to another end of the edge region away from the middle region.

19. The display device of claim 11, wherein the active layer comprises a first surface, a second surface, and a sidewall respectively connected to the first surface and the second surface and obliquely disposed, and the second surface is disposed on a side of the first surface away from the substrate;
wherein the sidewall is disposed in the edge regions, the first surface is disposed in the middle region and the edge regions, and the second surface is disposed in at least the middle region.

20. The display device of claim 19, wherein an included angle between the sidewall and the second surface is between 50 degrees and 80 degrees.
